(19) United States
(12) Patent Application Publication
(10) Pub. No.: US 2022/0090872 A1
(43) Pub. Date: Mar. 24, 2022

(54) WEAPON ENHANCED WITH THERMOELECTRIC COOLER SYSTEMS

(71) Applicant: TRUE VELOCITY IP HOLDINGS, LLC, Garland, TX (US)

(72) Inventor: Kenneth J. Overton, Princeton, TX (US)

(73) Assignee: True Velocity IP Holdings, LLC, Garland, TX (US)

(21) Appl. No.: 17/370,289

(22) Filed: Jul. 8, 2021

Related U.S. Application Data
(60) Provisional application No. 63/050,869, filed on Jul. 12, 2020.

(51) Int. Cl. F41A 13/10; H01L 35/02; H01L 35/32; F41A 13/02

(52) U.S. Cl. CPC F41A 13/10; F41A 13/02; H01L 35/32; H01L 35/02

(57) ABSTRACT

The present invention includes a weapon with a thermoelectric system for reducing the heat of the weapon, comprising: a weapon; one or more panels in contact with at least one region of the weapon, wherein the each of the one or more panels independently comprise an electrically and thermally insulating material; a plurality of thermoelectric elements; and a plurality of conductors comprising (i) a compacted portion that is compacted in cross section inside the panel and (ii) an expanded portion that is expanded in at least one dimension outside the panel, wherein the expanded portion of the plurality of conductors projects away from and is disposed adjacent to a surface of the panel and directly connects one thermoelectric element to another thermoelectric element of the plurality of thermoelectric elements, wherein the plurality of thermoelectric elements comprises alternating n-type and p-type thermoelectric elements.

### INCORPORATION-BY-REFERENCE OF MATERIALS FILED ON COMPACT DISC

This application claims the benefit of U.S. Provisional Patent Application Ser. No. 63/050,869 filed on Jul. 12, 2020 and is incorporated herein by reference.

### TECHNICAL FIELD OF THE INVENTION

The present invention relates in general to the field of thermoelectric coolers and/or heaters and more specifically to thermoelectric coolers and/or heaters interfaced with a weapons system to regulate heat generated thereby.

### STATEMENT OF FEDERALLY FUNDED RESEARCH

None.

### BACKGROUND OF THE INVENTION

Without limiting the scope of the invention, its background is described in connection with weapons platforms implementing thermoelectric devices to regulate the cooling and/or heating of various regions of a weapon.

It is known that when firing an automatic weapon, heating occurs during the combustion of gunpowder inside the ammunition cartridge in the chamber. In some instances, the overheating of the barrel of the weapon can occur due to the heat generated from the combustion of gunpowder inside the ammunition cartridge as well as the friction of the bullet on the inner surface of the barrel. In addition, over heating can occur through heat transfer in instances where the barrel is undersized for the application and depending on the barrel materials. As a result of overheating, the weapon can become inoperable. As a result of overheating of weapon trunks, a “haze” effect may be observed where heat fluxes from the barrel distort the field of view and the target becomes indistinguishable for a while due to the temperature bending of the hot trunk with unilateral exposure to wind or precipitation, the midpoint of hits is removed. This is especially true when using an optical sight. In a heated barrel, if the cartridge is in the chamber for a long time, a spontaneous shot may occur. The increase in the thickness of the walls of the barrel and the strengthening of the receiver can increase the intensity of fire; however, this increases weight.

Many approaches have been used to prevent overheating of the barrel on large-caliber machine gun DShK (12.7 mm large-caliber machine gun Degtyarev-Shpagin, model 1938 (USSR)) by ribbing in the form of rings is made on the outer surface of the barrel, which increases the surface of the barrel and improves its cooling, but this is not enough. Similarly, to cool machine-gun barrels, water cooling is also used. An example is the Maxim machine gun (7.62 mm Maxim machine gun, model 1910, USA/Russia). In the latest models of this machine gun, not only water was used, but also ice and snow. This greatly increased the weight of the weapon.

For example, U.S. Pat. No. 7,464,496, entitled, “Heat exchanger barrel nut” discloses a barrel nut for coupling a barrel of a firearm to a receiver includes a body having a first end, an opposing second end, and an outer surface. A bore extends centrally through the body from the first end to the second end. A plurality of heat conducting fins extends radially outwardly from the outer surface of the body. A fastening element fastens the breach end of the barrel nut to the receiver.

Other examples, include U.S. Pat. No. 10,584,933, entitled, “Firearm barrel cooling system” discloses a firearm barrel cooling system includes fins formed to extend around and from a barrel blank of a same material as the fins. An outside major diameter of the fins is greater than an outside diameter of the formed barrel near a shank of the barrel. Flutes are defined around and in the barrel blank between adjacent fins wherein an outside diameter of the flutes is equal to a minor diameter of the fins and equal to or greater than an outside diameter of the barrel. A transition from a crest of a flute to a base of a fin coincides with a taper of the formed barrel from shank to muzzle. Fin cooling sections are located between a barrel collar and a muzzle end of the formed barrel, each cooling section having a plurality of fins.

Other examples, include United States Patent Publication Number 2016/0273861, entitled, “Firearm Barrel Cooling System” discloses a firearm barrel cooling system comprising a plurality of fins adapted to extend around and from a solid barrel of a same material as the fins is disclosed. An outside major diameter of the fins is greater than an outside diameter of the barrel at any point of the barrel. A plurality of inverted fins are defined around and in the solid barrel between adjacent fins wherein an inside diameter of the inverted fins is equal to a minor diameter of the fins and equal to or greater than an outside diameter of the barrel. A plurality of cooling sections are located between a barrel collar and a muzzle end of the solid barrel, each cooling section having a plurality of fins having a major outer diameter and a minor inner diameter.

### SUMMARY OF THE INVENTION

The present invention provides a weapon having a thermoelectric system for heating or cooling, comprises a panel in contact with a portion of a weapon comprising an electrically and thermally insulating material; a plurality of thermoelectric elements comprising individual conductors that are (i) compacted in cross section inside the panel and (ii) expanded in at least one dimension outside the panel, wherein the individual conductors project away from and adjacent to a surface panel from one thermoelectric element to another thermoelectric element of the plurality of thermoelectric elements, wherein the plurality of thermoelectric elements comprises alternating n-type and p-type thermoelectric elements; and a thermally conductive cover adjacent to the surface of the panel, wherein the thermally conductive cover comprises a polymeric material, and wherein portions of the individual conductors that are expanded in the at least one dimension outside the panel are embedded in the cover. Wherein the portion of the weapon is the barrel, the receiver, the handguard, the stock, the magazine or a combination thereof.

A weapon having a thermoelectric system for cooling the weapon, comprising a weapon wherein a portion of the weapon is in contact with a panel comprising an electrically and thermally insulating material; and a plurality of thermoelectric elements comprising individual conductors that are (i) compacted in cross section inside the panel and (ii) expanded in at least one dimension outside the panel, wherein the individual conductors project away from and adjacent to a surface of the panel from one thermoelectric element to another thermoelectric element of the plurality of thermoelectric elements, wherein portions of the individual conductors that are expanded in the at least one dimension are at a first side of the panel, wherein the plurality of thermoelectric elements comprise loop portions on a second side of the panel that is opposite the first side of the panel, and wherein the plurality of thermoelectric elements comprises alternating n-type and p-type thermoelectric elements.

A weapon having a thermoelectric system for cooling the weapon positioned in contact with at least one heated portion of the weapon, wherein the thermoelectric system comprises a thermoelectric element, a hot source connected to the thermoelectric element and dissipating heat generated by the thermoelectric element, a cold sink for cooling an object, and supplying power to the thermoelectric element And a means for selectively and thermally connecting the thermoelectric element to the hot source so as to achieve high efficiency cooling.

A thermoelectric device for manipulating a temperature of a surface of a weapon, comprising: at least one thermoelectric material constructed and arranged to be disposed adjacent the surface; and a controller in electrical communication with the at least one thermoelectric material, the controller configured to cause the at least one thermoelectric material to generate a plurality of thermal pulses in succession at a region of the at least one thermoelectric material adjacent the surface, each of the thermal pulses including a first temperature adjustment at the region of the at least one thermoelectric material adjacent the surface from a first temperature to a second temperature at a first average rate between about 0.1° C./sec and about 10.0° C./sec, and a second temperature adjustment at the region of the at least one thermoelectric material adjacent the surface from the second temperature to a third temperature at a second average rate between about 0.1° C./sec and about 10.0° C./sec, wherein the controller is configured to cause the at least one thermoelectric material to generate each of the thermal pulses over a time period of less than 30 seconds, and wherein the controller is configured to cause the at least one thermoelectric material to generate each of the thermal pulses such that a difference in magnitude between the first temperature and the second temperature is less than 10° C.

### BRIEF DESCRIPTION OF THE DRAWINGS

For a more complete understanding of the features and advantages of the present invention, reference is now made to the detailed description of the invention along with the accompanying figures and in which:

FIG. 1 depicts a high-level block diagram of a Thermoelectric Cooling (TEC) device in accordance with the prior art;

FIG. 2 depicts a cross sectional view of a thermoelectric cooler with enhanced structured interfaces in accordance with the prior art;

FIG. 3 depicts a planer view of thermoelectric cooler in accordance with the prior art;

FIG. 4 is a schematically illustrates an insulating panel and thermoelectric string in accordance with the prior art;

FIG. 5 illustrates integration of an insulating panel with the spacer mesh material in accordance with the prior art; and

FIG. 6, which is a side view of a rifle in accordance with the prior art.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

As used herein, the term “TEC”, thermoelectric cooler, thermoelectric module, and Peltier module are used interchangeably to denote a semiconductor-based electronic component that functions as a small heat pump. By applying a low-voltage DC power source to a TEC, heat flows via the semiconductor elements from one face to the other. The electric current cools one face and simultaneously heats the opposite face. Consequently, a given face of the device can be used for heating or cooling by reversing the polarity of the applied current. The characteristics of TECs make them highly suitable for precise temperature control applications and where space limitations and reliability are paramount.

Weapons such as the AR-15, AR-10, M16 and the like include a receiver having a stock coupled to one end and a barrel coupled to the opposing end. A breach end of the barrel is received by the receiver and a barrel nut is used to fix the barrel in position. Over time, firing rounds through a firearm will degrade the mechanism and the barrel. While the barrel can be readily replaced, and damaged parts can also be replaced, replacement can be expensive. Even more important, during military and law enforcement use, the need to replace parts can occur at very inconvenient times posing a danger to the user. Additionally, prior to replacement, the accuracy of the barrel can be degraded by wear and/or distortion.

To a large degree, the degradation and even damage to the firearm can be attributed to excessive heating of metallic parts such as the barrel and elements within the receiver such as the extractor. During use, particularly in military situations where automatic fire is employed, high levels of heat are generated by the detonating cartridge and even more is generated by the friction of the bullet passing through the barrel. The heat is collected in the barrel and to some degree in the receiver. To protect a user, a firearm typically includes a handguard covering the barrel nut and the barrel. Unfortunately, while protecting a user, the handguard also contains the heat of the barrel, preventing dissipation. Barrel heat has long been known to cause damage, and has been addressed by the use of water jackets for water cooling in heavy machine guns and with perforated sleeves or handguards for air circulation. While somewhat effective for cooling the barrel, heat collected at the breach end of the barrel and within the receiver has not been addressed. Excessive heating and subsequent cooling can damage and degrade the barrel, the receiver and parts within the receiver.

The invention relates to weapons platforms that use thermoelectric devices to regulate the cooling and/or heating of various regions of a weapon in an effort to regulate temperature output of the weapon during or after operation. More specifically, the thermoelectric devices are used to regulate the heat and cool the barrel and to some degree in the receiver.

First turning to the thermoelectric coolers, any thermoelectric cooler may be used in this application provided the device is adapted to fit within or contact the portion of the weapon. The following examples of thermoelectric coolers are meant for illustration purposes and not to limit the invention to any specific design or thermoelectric cooler. For example, U.S. Pat. No. 6,403,876, entitled, “Enhanced Interface Thermoelectric Coolers with all-Metal Tips” is incorporated herein by reference. Other devices include U.S. Pat. Nos. 10,571,162; 10,393,414; 7,198,096; 7,838,760; 6,613,602; and 5653741 each of which is incorporated herein by reference.

For example, U.S. Pat. No. 10,182,937, entitled, “Methods and apparatuses for manipulating temperature,” incorporated herein by reference discloses methods and apparatuses for manipulating the temperature of a surface are provided. The devices may include a thermal adjustment apparatus, such as a controller in electrical communication with one or more thermoelectric materials, placed adjacent to the surface of skin.

For example, U.S. Pat. No. 10,571,162, entitled, “Integration of distributed thermoelectric heating and cooling,” incorporated herein by reference discloses a thermoelectric device including a panel, formed of a thermally insulating material, and having a plurality of thermoelectric elements including compacted conductors inside the insulating material and expanded conductors outside the insulating material wherein the thermoelectric elements run substantially parallel to or at an acute angle relative to the long dimension of the panel. The thermoelectric device may be integrated into a variety of surfaces or enclosures needing heating or cooling with controls and configurations to optimize the application.

As a general principle, thermoelectric coolers operate according to the Peltier effect. The effect creates a temperature difference by transferring heat between two electrical junctions. A typical single-stage cooler consists of two ceramic plates with “elements” of p-type and n-type semiconductor materials (e.g., bismuth telluride alloys) between the plates. The elements of semiconductor materials are connected electrically in series and thermally in parallel. When a positive DC voltage is applied, electrons pass from the p-type to the n-type element, and the cold-side temperature decreases as the electron current absorbs heat, until equilibrium is reached. When the current flows through the junctions of the two conductors, heat is removed at one junction and cooling occurs. Heat is deposited at the other junction. The heat absorption (cooling) is proportional to the current and the number of thermoelectric couples. This heat is transferred to the hot side of the cooler, where it is dissipated into the heat sink and surrounding environment. Solid solutions of bismuth telluride, antimony telluride, and bismuth selenide are the common materials for Peltier effect devices because they provide the best performance from 180 to 400 K and can be made both n-type and p-type.

In addition, multiple thermoelectric coolers may be used. The cooling effect of any unit using thermoelectric coolers is proportional to the number of coolers used. Typically, multiple thermoelectric coolers are connected side by side and then placed between two metal plates. For example, these multi thermoelectric coolers systems include thermocyclers, single stage, and multi-stage. In the thermoelectric coolers cooling occurs when a current passes through one or more pairs of elements from n- to p-type; there is a decrease in temperature at the junction (“cold side”), resulting in the absorption of heat from the environment. The heat is carried along the elements by electron transport and released on the opposite (“hot”) side as the electrons move from a high-energy state to low-energy state. The Peltier heat absorption can be easily calculated and a single stage thermoelectric cooler can produce a maximum temperature difference of about 70° Celsius.

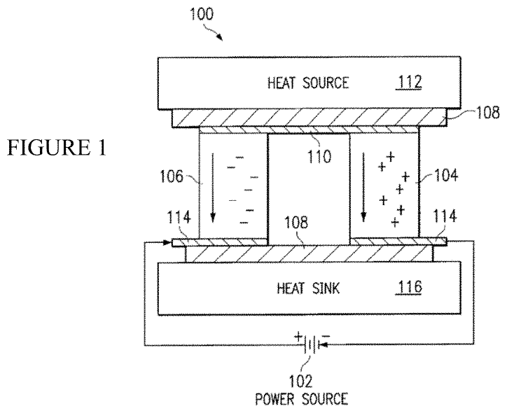

For exemplar purposes we know turn to FIG. 1 which is a high-level block diagram of a Thermoelectric Cooling device is depicted in accordance with the prior art. Thermoelectric cooling, a well known principle, is based on the Peltier Effect, by which DC current from power Source 102 is applied across two dissimilar materials causing heat to be absorbed at the junction of the two dissimilar materials. A typical thermoelectric cooling device utilizes p-type Semiconductor 104 and n-type Semiconductor 106 Sandwiched between poor electrical conductors 108 that have good heat conducting properties. N-type Semiconductor 106 has an excess of electrons, while p-type semiconductor 104 has a deficit of electrons. As electrons move from electrical conductor 110 to n-type Semiconductor 106, the energy state of the electrons is raised due to heat energy absorbed from heat source 112. This process has the effect of transferring heat energy from heat source 112 via electron flow through n-type Semiconductor 106 and electrical conductor 114 to heat sink 116. The electrons drop to a lower energy state and release the heat energy in electrical conductor 114. The coefficient of performance, m, of a cooling refrigerator, such as thermoelectric cooler 100, is the ratio of the cooling capacity of the refrigerator divided by the total power consumption of the refrigerator. Thus, the coefficient of performance is given by the equation:

$$η = \frac{{α IT}_{c} - \frac{1}{2} {I}^{2} R - K Δ T}{{I}^{2} R + α I Δ T}$$

where the term αIT is due to the thermoelectric cooling, the term (½)I²R is due to Joule heating backflow, the term KΔT is due to thermal conduction, the term I²R is due to Joule loss, the term αIΔT is due to work done against the Peltier voltage, α. is the Seebeck coefficient for the material, T_{c} is the temperature of the heat Source, and ΔT is the difference in the temperature of the heat Source from the temperature of the heat sink. The maximum coefficient of performance is derived by optimizing the current, I, and is given by the following relation:

$${η}_{max} = ( \frac{{T}_{c}}{Δ T} ) [ \frac{γ - \frac{{T}_{h}}{{T}_{c}}}{γ + 1} ]$$

$$where$$

$$γ = \sqrt{1 + \frac{{α}^{2} σ}{λ} ( \frac{{T}_{h} + {T}_{c}}{2} )}$$

$$and$$

$$ɛ = \frac{γ - \frac{{T}_{h}}{{T}_{c}}}{γ + 1}$$

where ε is the efficiency factor of the refrigerator. The figure of merit, ZT, is given by the equation:

$$ZT = \frac{{α}^{2} σ T}{λ}$$

where λ is composed of two components: λₑ the component due to electrons, and λ_{L}, the component due to the lattice. Therefore, the maximum efficiency, ε, is achieved as the figure of merit, ZT, approaches infinity. The efficiency of Vapor compressor refrigerators is approximately 0.3. The efficiency of conventional thermoelectric coolers, Such as thermoelectric cooler 100 in FIG. 1, is typically less than 0.1. Therefore, to increase the efficiency of thermoelectric coolers to such a range as to compete with vapor compression refrigerators, the figure of merit, ZT, must be increased to greater than 2. If a value for the figure of merit, ZT, of greater than 2 can be achieved, then the thermoelectric coolers may be Staged to achieve the same efficiency and cooling capacity as vapor compression refrigerators.

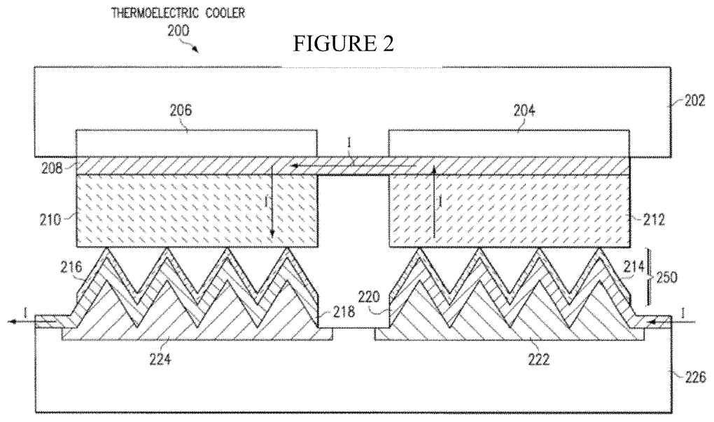

With reference to FIG. 2, a cross sectional view of a thermoelectric cooler with enhanced Structured interfaces is depicted in accordance with the present invention. Thermoelectric cooler 200 includes a heat source 226 from which, with current I flowing as indicated, heat is extracted and delivered to heat sink 202. Heat source 226 may be thermally coupled to a substance that is desired to be cooled. Heat sink 202 may be thermally coupled to devices such as, for example, a heat pipe, fins, and/or a condensation unit to dissipate the heat removed from heat Source 226 and/or further cool heat Source 226. Heat Source 226 is comprised of p-type doped Silicon. Heat Source 226 is thermally coupled to n+ type doped silicon regions 224 and 222 of tips 250. n+ type regions 224 and 222 are electrical conducting as well as being good thermal conductors. Each of n+ type regions 224 and 222 forms a reverse diode with heat Source 226 Such that no current flows between heat Source 226 and n+ regions 224 and 222, thus providing the electrical isolation of heat Source 226 from electrical conductors 218 and 220.

Heatsink 202 is comprised of p-type doped silicon. Heat Sink 202 is thermally coupled to n+ type doped Silicon regions 204 and 206. n+ type regions 204 and 206 are electrically conducting and good thermal conductors. Each of n+ type regions 204 and 206 and heat sink 202 forms a reverse diode so that no current flows between the n+ type regions 204 and 206 and heat sink 202, thus providing the electrical isolation of heatsink 202 from electrical conductor 208. More information about electrical isolation of thermoelectric coolers may be found in commonly U.S. patent application Ser. No. 09/458,270 entitled “Electrically Isolated Ultra-Thin Substrates for Thermoelectric Coolers”, the contents of which are hereby incorporated herein for all purposes. The need for forming reverse diodes with n+ and p-regions to electrically isolate conductor 208 from heat sink 202 and conductors 218 and 220 from heat Source 226 is not needed if the heat sink 202 and heat Source 226 are constructed entirely from undoped non-electrically conducting silicon. However, it is very difficult to ensure that the silicon is entirely undoped. Therefore, the presence of the reverse diodes provided by the n+ and p− regions ensures that heat sink 202 and heat source 226 are electrically isolated from conductors 208, 218, and 220. Also, it should be noted that the same electrical isolation using reverse diodes may be created other ways, for example, by using p+ type doped Silicon and n− type doped silicon rather than the p− and n+ types depicted. The terms n+ and p+, as used herein, refer to highly n doped and highly p doped Semiconducting material respectively. The terms n− and p−, as used herein, mean lightly n doped and lightly p doped Semiconducting material respectively.

Thermoelectric cooler 200 is similar in construction to thermoelectric cooler 100 in FIG. 1. However, N-type 106 and P-type 104 semiconductor structural interfaces have been replaced with Superlattice thermoelement Structures 210 and 212 that are electrically coupled by electrical conductor 208. Electrical conductor 208 may be formed from platinum (Pt) or, alternatively, from other conducting materials, Such as, for example, tungsten (W), nickel (Ni), or titanium copper nickel (Ti/Cu/Ni) metal films.

A Superlattice is a structure consisting of alternating layers of two different Semiconductor materials, each Several nanometers thick. Thermoelement 210 is constructed from alternating layers of n-type Semiconducting materials and the Superlattice of thermoelement 212 is constructed from alternating layers of p-type Semiconducting materials. Each of the layers of alternating materials in each of thermoelements 210 and 212 is 10 nanometers (nm) thick. A super lattice of two Semiconducting materials has lower thermal conductivity, and the same electrical conductivity, O, as an alloy comprising the same two Semiconducting materials. In one embodiment, Superlattice thermoelement 212 comprises alternating layers of p-type bismuth chalcogenide materials. Such as, for example, alternating layers of Bi₂Te₃/Sb₂Te₃, with layers of Bi_{0.5}Sb_{1.5}Te₃, and the Superlattice of thermoelement 210 comprises alternating layers of n-type bismuth chalcogenide materials, Such as, for example, alternating layers of Bi₂Te₃ with layers of Bi₂Se₃. Other types of Semiconducting materials may be used for Superlattices for thermoelements 210 and 212 as well. For example, rather than bismuth chalcogenide materials, the Superlattices of thermoelements 210 and 212 may be constructed from cobalt antimony Skutteridite materials. Thermoelectric cooler 200 also includes tips 250 through which electrical current I passes into thermoelement 212 and then from thermoelement 210 into conductor 218. Tips 250 includes n+ type Semiconductor 222 and 224 formed into pointed conical Structures with a thin overcoat layer 218 and 220 of conducting material, Such as, for example, platinum (Pt). Other conducting materials that may be used in place of platinum include, for example, tungsten (W), nickel (Ni), and titanium copper nickel (Ti/Cu/Ni) metal films. The areas between and around the tips 250 and thermoelectric materials 210 and 212 should be evacuated or hermetically sealed with a gas Such as, for example, dry nitrogen. On the ends of tips 250 covering the conducting layers 218 and 220 is a thin layer of semiconducting material 214 and 216. Layer 214 is formed from a P-type material having the same Seebeck coefficient, C, as the nearest layer of the Superlattice of thermoelement 212 to tips 250. Layer 216 is formed from an N-type material having the same Seebeck coefficient, C., as the nearest layer of thermoelement 210 to tips 250. The P-type thermoelectric overcoat layer 214 is necessary for thermoelectric cooler 200 to function since cooling occurs in the region near the metal where the electrons and holes are generated. The n-type thermoelectric overcoat layer 216 is beneficial, because maximum cooling occurs where the gradient (change) of the Seebeck coefficient is maximum. The thermoelectric overcoat 214 for the P-type region is approximately 60 nm thick. A specific thickness of the n-type thermoelectric overcoat 216 has yet to be fully refined, but it is anticipated that it should be in a Similar thickness range to the thickness of the thermoelectric overcoat 214.

By making the electrical conductors, such as, conductors 110 in FIG. 1, into pointed tips 250 rather than a planer interface, an increase in cooling efficiency is achieved. Lattice thermal conductivity, λ, at the point of tips 250 is very Small because of lattice mismatch. For example, the thermal conductivity, λ, of bismuth chalcogenides is normally approximately 1 Watt/meter*Kelvin. However, in pointed tip structures, Such as, tips 250, the thermal conductivity is reduced, due to lattice mismatch at the point, to approximately 0.2 Watts/meter*Kelvin. However, the electrical conductivity of the thermoelectric materials remains relatively unchanged. Therefore, the figure of merit, ZT, may increased to greater than 2.5 for this kind of material. Another type of material that is possible for the Superlattices of thermoelements 210 and 212 is cobalt antimony Skutteridites. These type of materials typically have a very high thermal conductivity, λ, making them normally undesirable. However, by using the pointed tips 250, the thermal conductivity can be reduced to a minimum and produce a figure of merit, ZT, for these materials of greater than 4, thus making these materials very attractive for use in thermoelements 210 and 212. Therefore, the use of pointed tips 250 further increases the efficiency of the thermoelectric cooler 200 such that it is comparable to vapor compression refrigerators.

Another advantage of the cold point Structure is that the electrons are confined to dimensions Smaller than the wavelength (corresponding to their kinetic energy). This type of confinement increases the local density of States available for transport and effectively increases the Seebeck coefficient. Thus, by increasing a and decreasing λ, the figure of merit ZT is increased.

Normal cooling capacity of conventional thermoelectric coolers, Such as, illustrated in FIG. 1, are capable of producing a temperature differential, AT, between the heat Source and the heat sink of around 60 Kelvin. However, thermoelectric cooler 200 is capable of producing a temperature differential on the order of 150 Kelvin. Thus, with two thermoelectric coolers coupled to each other, cooling to temperatures in the range of liquid Nitrogen (less than 100 Kelvin) is possible.

However, different materials may need to be used for thermoelements 210 and 212. For example, bismuth telluride has a very low C at low temperature (i.e. less than −100 degrees Celsius). However, bismuth antimony alloys perform well at low temperature.

Another advantage of the cobalt antimony Skutteridite materials over the bismuth chalcogenide materials, not related to temperature, is the fact that cobalt antimony Skutteridite materials are structurally more stable whereas the bismuth chalcogenide materials are structurally weak.

Those of ordinary skill in the art will appreciate that the construction of the thermoelectric cooler in FIG. 2 may vary depending on the implementation. For example, more or fewer rows of tips 250 may be included than depicted in FIG. 1. The depicted example is not meant to imply architectural limitations with respect to the present invention.

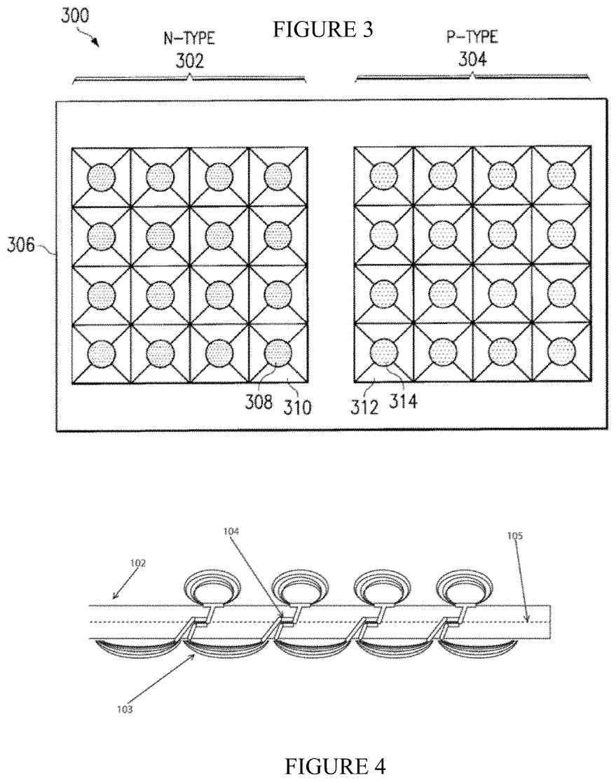

With reference now to FIG. 3, a planer view of thermoelectric cooler 200 in FIG. 2 is depicted in accordance with the present invention. Thermoelectric cooler 300 includes an n− type thermoelectric material section 302 and a p-type thermoelectric material section 304. Both n-type section 302 and p-type section 304 include a thin layer of conductive material 306 that covers a silicon body.

Section 302 includes an array of conical tips 310 each covered with a thin layer of n-type material 308 of the same type as the nearest layer of the Superlattice for thermoelement 210. Section 304 includes an array of conical tips 312 each covered with a thin layer of p-type material 314 of the same type as the nearest layer of the Superlattice for thermoelement 212.

FIG. 4 is a schematically illustrates an insulating panel and thermoelectric string in accordance with the prior art. FIG. 4 shows an alternative thermoelectric panel wherein the rigid elements 104 run essentially parallel to the long dimension of the panel, again eliminating the lumpy feeling. Because the entry holes and the exit holes of the string 103 are not co-linear, standard insertion techniques, e.g. such as poking through of the insulating material may not be possible. Hence, FIG. 4 shows the elongate insulating panel divided into two halves along a bond line 105. The elements 104 are placed between the halves, which is then re-bonded after assembly. Another approach is to inject the insulating material 102 into a mold with horizontally placed elements 104 so that the elements 104 will be molded in-situ oriented substantially parallel to or angled to the long dimension of the panel.

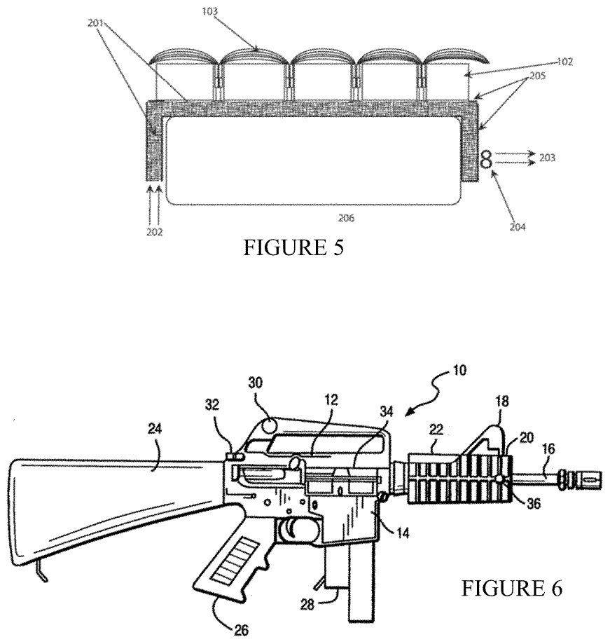

FIG. 5 illustrates integration of an insulating panel with the spacer mesh material in accordance with the prior art. FIG. 5 illustrate the provision of an air flow cavity to remove the heat from the hot side during cooling or to replenish heat from the environment during heating. The manufacturer describes this material as a two layer spacer fabric separated by an open mesh which provides a highly vacated cavity for airflow. The material is capable of supporting the pressure of a person sitting on the material without collapsing the cavity. This spacer mesh is oriented underneath an elongated heated and cooled panel surface 102 as shown in FIG. 5. Fan(s) 204 provide air flow which removes heat via convection from the hot sides of the thermoelectric string 103. The spacer mesh 201 is sealed with an air-tight seal 205 in order to force the airflow into a desired path, in this case through the length of the spacer mesh 201. The configuration of FIG. 5 may be placed on top of a bed, the seat or back of a chair, or the surface of a stretcher or the seat or back of a wheelchair or any other surface 206, without limitation, where upgrade to a heated and cooled support surface is desired. Without limitation, the spacer mesh could be replaced with any porous material such as reticulated foam.

FIG. 6, which is a side view of a rifle known in the prior art, a rifle 10 consists of an upper receiver 12 attached to a lower receiver 14 and having a barrel 16 threadedly engaged in the upper receiver 12. Barrel 16 may include an attached front sight 18 and is partially enclosed by a handguard assembly 20. Barrel 16 has a gas port (not shown) passing through the top portion of the barrel from the bore to communicate with a gas cylinder assembly 22 lying above and substantially parallel to the barrel. The upper and lower receivers 12 and 14 respectively, are braced by the buttstock assembly 24, which is threadedly attached to the lower receiver 14 and contains a buffer spring assembly (not shown) therein. A handgrip 26 is attached to the lower receiver directly behind the trigger assembly. A removable magazine 28 fits in the magazine well of lower receiver 14 and provides a cartridge feeding assembly. A rear sight assembly 30 may be adjustably mounted in upper receiver 12. A charging handle 32 is slidably located in upper receiver 12 and also slidably engages bolt assembly 34.

List of combat rifle that can be used with the thermoelectric cooler of the present invention including but not limited to AB-3, Adaptive Combat Rifle, ADS amphibious rifle, AEK-971, AG-043, Ak 5, AK-9, AK-12, AK-47, AK-63, AK-74, AK-101, AK-103, MPT-55, KH-2002 Khaybar, AK-107, AKM, AMD-65, AMP-69, AN-94, AO-27 rifle, AO-31, AO-35 assault rifle, AO-38 assault rifle, APS-95, APS underwater rifle, AS Val, ASM-DT amphibious rifle, Barrett REC7, Beretta AR70/90, Beretta ARX160, Beretta Rx4 Storm, BSA 28P, BR18, Chropi rifle, CEAM Modèle 1950, CETME Model L, Close Quarters Battle Receiver, C7 rifle, Colt CM901, Conventional Multirole Combat Rifle, CZ 805 BREN, C̆Z 2000, Daewoo K2, Desarrollos Industriales Casanave SC-2005, Dlugov assault rifle, EM-2 rifle, Excalibur rifle, EMER K1, FAMAS, FARA 83, FB Beryl, FB MSBS, FB Tantal, FN CAL, FN F2000, FN FNC, FN SCAR-L, FX-05 Xiuhcoatl, Grad AR, Grossfuss Sturmgewehr, Heckler & Koch G11, Heckler & Koch G36, Heckler & Koch G41, Heckler & Koch HK33, Heckler & Koch HK36, Heckler & Koch HK416 (M27 Infantry Automatic Rifle), Heckler & Koch HK433, Howa Type 20, Howa Type 89, HS Produkt VHS, IMBEL MD, IMBEL IA2, IMI Galil, IWI Tavor, IWI X95, Ingram FBM, INSAS rifle[6], Interdynamics MKS, Itajuba OVM, IWI ACE, Kbkg wz. 1960, Komodo Armament D5, Komodo Armament D7, L64/65, L85, Leader Dynamics Series T2 MK5, LR-300, LSAT rifle, M-16/M-4, Multi Caliber Individual Weapon System, Nesterov assault rifle, Norinco CQ, OTs-12 Tiss, OTs-14 Groza, Pindad SS1, Pindad SS2, Pistol Mitralieră model 1963/1965, Puşcă Automată model 1986, PVAR rifle, QBZ-95/QBZ-97, QBZ-03, Remington R4, Remington R5 RGP, Rk 62, Rk 95 TP, Robinson Armament XCR, S&T Daewoo K11, Sa vz. 58, SAR 80, SAR-21, SIG MCX, SIG Sauer SIG516, SIG SG 530, SIG SG 540, SIG SG 550, SOCIMI AR-831, Special Operations Assault Rifle, SR-3 Vikhr, SR-47, SR 88, Sterling SAR-87, Steyr AUG, Stoner 63, StG 44, StG 45(M), T65 assault rifle, T86 assault rifle, T91 assault rifle, TKB-072, TKB-517, Trichy Assault Rifle, Type 56 assault rifle, Type 58 assault rifle, Type 63 assault rifle, Type 81 assault rifle, Norinco Type 86S, VAHAN (firearm), Valmet M76, Valmet M82, VB Berapi LP06, Vektor CR-21, Vektor R4, Vepr, Wieger StG-940, Wimmersperg Spz, XM8 rifle, XT-97 Assault Rifle, Zastava M21, Zastava M70, Zastava M80, Zastava M90 or any yet developed gun having similar components and/or layouts.

List of machine guns that can be used with the thermoelectric cooler including but not limited to TKK 31 VKT; AA-52; UP 7.62; HP 7.62; AEK-999; Ares Shrike 5.56; Bailey machine gun; Barnitzke machine gun; Beretta AS70/90; Berezin UB; Bergmann MG 15nA machine gun; Besa machine gun; Besal; Breda 30; Breda 38; Breda M37; Breda Mod. 5C; Breda-SAFAT machine gun; Bren light machine gun; Browning wz.1928; CETME Ameli; Charlton Automatic Rifle; Chauchat; STK 50MG; Ckm wz.30; Colt Machine Gun; Colt Automatic Rifle; Daewoo K3; Darne machine gun; Degtyaryov machine gun; DShK; Dror light machine gun; DS-39; EMER-K1 LMG; EPK (Pyrkal) Machine gun; Fiat-Revelli Modello 1914; Fiat-Revelli Modello 1935; Fittipaldi machine gun; FM 24/29 light machine gun; FN BRG-15; FN MAG; FN Minimi; Fokker-Leimberger; Furrer M25; Gatling gun; GAU-19; Gorgas machine gun; Heckler & Koch HK21; Heckler & Koch MG4; Heckler & Koch MG5; HMG PK-16; Hotchkiss M1909; Benét-Mercié; Hotchkiss M1914 machine gun; Hotchkiss M1922 machine gun; Hotchkiss M1929 machine gun; Huot Automatic Rifle; IMI Negev; IP-2; INSAS LMG; Kg m/40 light machine gun; Kk 62; Knight's Armament Company LMG; Kord machine gun; KPV heavy machine gun; Ksp m/42 machine gun; L86 LSW; Lahti-Saloranta M/26; Lewis gun; LSAT light machine gun; M2 Browning machine gun; M27 IAR; M60 machine gun; M85 machine gun; M240 machine gun; M249 light machine gun; M1895 Colt-Browning machine gun; M1917 Browning machine gun; M1918 Browning Automatic Rifle; M1919 Browning machine gun; M1921 Browning machine gun; M1926 machine gun; M1941 Johnson machine gun; MAC-58; MAC 1931; MAC 1934; Madsen-Saetter machine gun; Mark 48 machine gun; Maxim-Tokarev; McCrudden light machine rifle; Mendoza C-1934; Mendoza RM2; MG 08; MG 11; MG 13; MG 15; MG 17 machine gun; MG 30; MG 34; MG 39 Rh; MG 42; MG 45; MG 51; MG 81; MG 131; Minigun; Mini-SS; Nikonov machine gun; NSV machine gun; Parabellum MG 14; Pecheneg machine gun; Perino Model 1908; Pindad SM-2; PK machine gun; PM M1910; PMT-76; Puteaux APX Machine Gun; QBB-95; QJY-88; Rheinmetall MG 3; Rheinmetall MG 60; Rheinmetall RMG.50; Rolls-Royce Experimental Machine Gun; RPD; RPK; S&T Motiv K12; Salvator-Dormus M1893; Schwarzlose MG M.07/12; SG-43 Goryunov; SIG MG 710-3; Sterling 7.62; St. Étienne Mle 1907; Stoner 63/63A Light Machine Gun; Sumitomo Type 62; T24 machine gun; Taden gun; Type 1 heavy machine gun; Type 3 heavy machine gun; Type 11 light machine gun; Type 67 machine gun; Type 77 heavy machine gun; Type 80 machine gun; Type 81 squad machine gun; Type 90 machine gun; Type 92 machine gun; Type 92 heavy machine gun; Type 96 light machine gun; Type 97 light machine gun; Type 99 light machine gun; UKM-2000; Ultimax 100; Uk vz. 59; Vektor SS-77; Vickers .50 machine gun; Vickers-Berthier; Vickers K machine gun (VGO); Vickers machine gun; VMG 1927; W85 heavy machine gun; Weibel M/1932; XM133 Minigun; XM312; Zastava M02 Coyote; Zastava M72; Zastava M77; Zastava M84; Zastava M87; ZB-50; ZB-53; ZB vz. 26; ZB vz. 30; or any yet developed gun having similar components and/or layouts.

List of multiple-barrel machine guns that can be used with the thermoelectric cooler including but not limited to M197; Caldwell machine gun; Fokker-Leimberger; Fyodorov-Shpagin Model 1922; Gast gun; GAU-8; GAU-12 Equalizer; GAU-19; Gryazev-Shipunov GSh-6-23; Gryazev-Shipunov GSh-30-2; GShG-7.62 machine gun; M61 Vulcan; Minigun; Nikonov machine gun; Nordenfelt gun; MG14Z; Rheinmetall RMG 7.62; Twin Bren; Type 89 machine gun; Type 100 machine gun; XM214 Microgun; WLKM 12.7; Yak-B 12.7 mm machine gun; or any yet developed gun having similar components and/or layouts.

The present invention uses thermoelectric devices for heating and cooling of various regions of a weapon. For example, a thermoelectric cooler can be placed in the area of the barrel, handguard and/or chamber of the weapon to absorb the heat generated from the firing of a round in semi-automatic and automatic fire. The heat generated during the firing process contacts the thermoelectric cooler where it is cooled.

In another example, a thermoelectric cooler can be placed in the area of the barrel, handguard and/or chamber of the weapon to absorb the heat generated from the firing of a round in semi-automatic and automatic fire and cool the area. A second thermoelectric cooler can be placed in the area of the trigger and configured to heat the trigger assembly (I.e., for use in cold weather climate).

In another example, a thermoelectric cooler can be placed in the area of the barrel, handguard and/or chamber of the weapon and connected to a control unit that is capable of reversing the temperature change depending on the needs at that time. For example, the thermoelectric cooler can be placed in the area of the barrel, handguard and/or chamber of the weapon and set to warm the barrel and chamber during the initial firings and switched to cooling the barrel, handguard and/or chamber of the weapon as the heat increases during use.

In another embodiment of the instant invention, the system includes a power supply (e.g., battery etc.) that is recharges as the thermoelectric cooler is used for cooling or heating. Similarly a control unit may be used to regulate the cooling of the device, regulate flow through the thermoelectric cooler, change the flow direction to reverse the cooling or heating, direct flow to a power supply to recharge the power supply or to store the energy for later use. In addition, the number of thermoelectric coolers is only dependent on the size and placement of the individual devices. As such they may be configured, stacked, overlapped or otherwise positioned in sufficient number to accomplish the purpose.

The present invention includes a means for selectively and thermally connecting is a micro thermoelectric mechanical switch.

The present invention includes a means for selectively and thermally connecting is a solid-state heat switch.

The present invention includes a means for supplying power to the thermoelectric element and the means for selectively and thermally connecting the thermoelectric element are operable in a functionally synchronized manner.

The present invention includes a thermoelectric element is selectively switched to the hot source when the means for supplying power to the thermoelectric element is not operating.

The present invention includes a continuous heat path from said thermoelectric element and said hot source.

The present invention includes a device for manipulating a temperature of a surface, comprising: at least one thermoelectric material constructed and arranged to be disposed adjacent the surface; and a controller in electrical communication with the at least one thermoelectric material, the controller configured to cause the at least one thermoelectric material to generate a plurality of thermal pulses in succession at a region of the at least one thermoelectric material adjacent the surface, each of the thermal pulses including a first temperature adjustment at the region of the at least one thermoelectric material adjacent the surface from a first temperature to a second temperature at a first average rate between about 0.1° C./sec and about 10.0° C./sec, and a second temperature adjustment at the region of the at least one thermoelectric material adjacent the surface from the second temperature to a third temperature at a second average rate between about 0.1° C./sec and about 10.0° C./sec, wherein the controller is configured to cause the at least one thermoelectric material to generate each of the thermal pulses over a time period of less than 30 seconds, and wherein the controller is configured to cause the at least one thermoelectric material to generate each of the thermal pulses such that a difference in magnitude between the first temperature and the second temperature is less than 10° C.

The present invention includes a controller is configured to cause the at least one thermoelectric material to generate each of the thermal pulses such that a magnitude of the first average rate is greater than a magnitude of the second average rate.

The present invention includes a magnitude of the first average rate is different than a magnitude of the second average rate.

The present invention includes a controller configured to cause the at least one thermoelectric material to generate each of the thermal pulses such that a difference in magnitude between the first temperature and the third temperature is less than 10% of the difference in magnitude between the first temperature and the second temperature.

The present invention includes a controller configured to apply an electrical signal to the at least one thermoelectric material at a duty cycle of between about 1% and about 50%.

The present invention includes a controller configured to apply a first square wave electrical signal to the at least one thermoelectric material to generate at least a portion of the first temperature adjustment, and a second square wave electrical signal to the at least one thermoelectric material to generate at least a portion of the second temperature adjustment, wherein a magnitude of the first square wave electrical signal is greater than a magnitude of the second square wave electrical signal.

The present invention includes at least one thermoelectric material includes a plurality of thermoelectric materials located adjacent one another along the surface. The present invention includes at least one sensor in electrical communication with the thermoelectric cooler, wherein the thermoelectric cooler is controlled at least partially based on information from the at least one sensor. The present invention is operated using a feedback loop based at least partially on the information. The at least one sensor senses at least one selected from the group of humidity, moisture, ambient air temperature, a temperature difference between ambient air and the thermal adjustment apparatus, and a temperature difference between the surface and the thermal adjustment apparatus. The at least one sensor senses a physical parameter of a user.

The present invention can be used to heat or cool portions or all of the weapon, to heat or cool the barrel for prewarming or cooling, to heat or cool the ammunition magazine, the chamber or other portions of the weapon. In addition, the present invention may be used to regenerate or recapture power by conversion of heat energy into electrical energy. This energy may be stored in a battery, capacitor or other device integrated into the weapon or magazine or in communication with the weapon or magazine. For example, the heat produced from firing may be converted into electrical energy that is used for the optical sights, night vision, communications, transponder, location device, RFID device and so forth.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, MB, BBC, AAABCCCC, CBBAAA, CABABB, and so forth. The skilled artisan will understand that typically there is no limit on the number of items or terms in any combination, unless otherwise apparent from the context.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

What is claimed is:

1. A weapon with a thermoelectric system for reducing the heat of the weapon, comprising:
a weapon;
one or more panels in contact with at least one region of the weapon, wherein the each of the one or more panels independently comprise an electrically and thermally insulating material; a plurality of thermoelectric elements; and a plurality of conductors comprising (i) a compacted portion that is compacted in cross section inside the panel and (ii) an expanded portion that is expanded in at least one dimension outside the panel, wherein the expanded portion of the plurality of conductors projects away from and is disposed adjacent to a surface of the panel and directly connects one thermoelectric element to another thermoelectric element of the plurality of thermoelectric elements, wherein the plurality of thermoelectric elements comprises alternating n-type and p-type thermoelectric elements.

2. The thermoelectric system of claim 1, wherein the plurality of thermoelectric elements is parallel to the surface of the panel, incorporated into the handguard to contact the barrel or both.

3. The thermoelectric system of claim 1, wherein the panel comprises a molded material and the plurality of thermoelectric elements is at least partially molded within the molded material.

4. The thermoelectric system of claim 1, wherein the panel comprises a fluid flow cavity adjacent to an opposite surface of the panel, wherein the expanded portion of the plurality of conductors projects into the cavity.

5. The thermoelectric system of claim 4, wherein the fluid flow cavity comprises a porous material, a spacer mesh, or a reticulated foam material.

6. The thermoelectric system of claim 4, further comprising at least one fan to facilitate flow of heat away from a hot side of the panel during cooling or to facilitate flow of heat to a cold side of the panel during heating.

7. The thermoelectric system of claim 6, wherein the at least one fan is in in fluid communication with the fluid flow cavity, and wherein the at least one fan is configured to facilitate fluid flow through the fluid flow cavity to facilitate heat flow to or from the plurality of thermoelectric elements.

8. The thermoelectric system of claim 4, further comprising at least one unsealed fluid inlet and at least one unsealed fluid outlet in fluid communication with the fluid flow cavity.

9. The thermoelectric system of claim 4, further comprising a seal adjacent to one or more surfaces of the fluid flow cavity.

10. The thermoelectric system of claim 1, wherein the plurality of thermoelectric elements is mounted to or encapsulated by a strain-relieving material.

11. The thermoelectric system of claim 10, wherein the strain-relieving material comprises a composite material, a polymeric material, glass, or a combination thereof.

12. The thermoelectric system of claim 1, further comprising an electronic component that is electrically in parallel with the plurality of thermoelectric elements, wherein the electronic component prevents a single point of failure from creating an open circuit fault and disrupting current flow to the plurality of thermoelectric elements.

13. The thermoelectric system of claim 12, wherein the electronic component comprises a diode, an anti-fuse, or a shunt.

14. The thermoelectric system of claim 1, further comprising a plurality of panels including the panel, wherein each of the plurality of panels is independently controllable.

15. The thermoelectric system of claim 1, further comprising at least one switch connected to a controller that activates or deactivates the plurality of thermoelectric elements.

16. The thermoelectric system of claim 15, wherein the at least one switch is a thermal sensor, pressure sensor, motion detector, or a combination thereof.

17. A thermoelectric system for heating or cooling at least a portion of a weapon, comprising a panel comprising an electrically and thermally insulating material;
a plurality of thermoelectric elements comprising individual conductors that are (i) compacted in cross section inside the panel and (ii) expanded in at least one dimension outside the panel, wherein the individual conductors project away from and adjacent to a surface panel from one thermoelectric element to another thermoelectric element of the plurality of thermoelectric elements, wherein the plurality of thermoelectric elements comprises alternating n-type and p-type thermoelectric elements; and
a thermally conductive cover adjacent to the surface of the panel, wherein the thermally conductive cover comprises a polymeric material, and wherein portions of the individual conductors that are expanded in the at least one dimension outside the panel are embedded in the cover.
